(19) United States
(12) Patent Application Publication
(10) Pub. No.: US 2024/0183445 A1
(43) Pub. Date: Jun. 6, 2024

(54) HIGH-EFFICIENCY SEAL COMPOSED OF CARBON NANOTUBES

(71) Applicant: UT-Battelle, LLC, Oak Ridge, TN (US)

(72) Inventors: Jun Qu, Oak Ridge, TN (US); Chanaka K. IhalaGamaralalage, Oak Ridge, TN (US); Tianlei Li, Oak Ridge, TN (US)

(21) Appl. No.: 18/371,817

(22) Filed: Sep. 22, 2023

Related U.S. Application Data
(60) Provisional application No. 63/429,192, filed on Dec. 1, 2022.

(51) Int. Cl. F16J 15/06; C23C 16/26; C23C 16/455

(52) U.S. Cl. CPC F16J 15/06; C23C 16/26; C23C 16/45557

(57) ABSTRACT

The disclosure relates to a sealing device comprising a sealing device comprising an annular substrate comprising an inner periphery defining a shaft hole; and a plurality of carbon nanotubes extending outwardly from and around the inner periphery into the shaft hole. In various practices, a plurality of annular metal mesh substrates is axially interposed and sandwiched between the first annular frame and a second annular frame, with a portion of the substrates comprising the carbon nanotubes extending outwardly from and around the inner periphery into the shaft hole. In another practice, the a solid annular metal substrate is used and a plurality of carbon nanotubes that extend into the shaft hole each have a first end attached to the inner periphery whereby the second end extends into the shaft hole. The device is useful in e.g. gas compressors.

### CROSS REFERENCED TO RELATED APPLICATION

The present application claims benefit of priority of U.S. Provisional Application No. 63/429,192, filed, Dec. 1, 2022, the entire contents of which are incorporated herein by reference.

### STATEMENT REGARDING FEDERALLY SPONSORED RESEARCH

The United States Government has rights in this invention pursuant to contract no. DE-AC05-00OR22725 between the United States Department of Energy and UT-Battelle, LLC.

### FIELD

The disclosure relates generally to sealing devices useful, for example, in gas compressors such as found in turbine machinery; assemblies comprising such sealing devices, and methods to make same.

### BACKGROUND

The internal leakage flow in gas compressors causes significant thermodynamic cycle loss. The sealing technologies have undergone constant development and improvement in last several decades. The state-of-the-art brush seal is an alternative to the conventional finned labyrinth seal and has demonstrated improved sealing capability and stability in turbomachinery. A brush seal is made up of a stationary brush ring, which consists of densely packed bristles, bound by front and back plates. These bristles are fine metallic or nonmetallic wires of typically 0.05-0.15 mm in diameter.

A tradeoff, however, has to be made between sealing efficiency (with a smaller clearance between the seal and rotating shaft preferred) and the friction and wear issues for the seal interfering the shaft spinning inside (here, a larger clearance preferred). Brush seals are commonly employed for these purposes. Brush seals are usually designed to have contact between the brush bristles and shaft. Since the brush bristles are in contact with the shaft, frictional drag or energy loss is inevitable. In addition, there is wear risk at the brush and shaft interface. Compared with replacing the seal, the cost of refinishing a shaft would be much higher. The types of brush seal bristles currently used typically are made from metal, (e.g. Haynes alloy, which is a cobalt-based alloy), or Kevlar fibers, or carbon fibers. Each has its drawbacks. For example, the metal bristle brush seal often seals better than a finned labyrinth seal, but poorer than a Kevlar fiber bristle seal or a carbon fiber bristle seal, and it experiences undue wear issues on both the metal bristles, e.g. lost bristles, and on the shaft, e.g. significant surface scratching of same. The current price for a Haynes alloy brush bristle seal is about $600. The Kevlar bristle brush seal often performs well in both sealing efficiency and durability, but it is very expensive, about $1800. The carbon fiber bristle brush seal often provides good sealing efficiency, but many of the carbon fibers fracture or become entirely removed from the seal during use requiring repair or replacement. The high cost of current brush seals is due in part to the high cost of the complex manufacturing process involved to produced them. Manufacturing of known brush seals involves core spring forming, braiding bristles, assembling, and final cut on the bristle dimension. There is thus a need for an improved sealing device that performs well and is cost effective.

### SUMMARY

In one aspect, the disclosure is directed to a sealing device comprising an annular substrate comprising an inner periphery defining a shaft hole; and a plurality of carbon nanotubes extending outwardly from and around the inner periphery into the shaft hole. In one practice, the annular substrate comprises a first annular frame member and a second annular frame member. wherein the second annular frame member is axially disposed relative to the first annular frame member; and the sealing device comprises one or a plurality of annular metal mesh substrates (e.g. up to 100 or more) that are axially interposed between the first annular frame and a second annular frame, wherein a portion of the one or more annular metal substrates extends outwardly from and around the inner periphery into the shaft hole, the portion comprising the carbon nanotubes. In another practice, the annular substrate comprises a solid metal substrate, and the plurality of carbon nanotubes that extend outwardly from and around the inner periphery into the shaft hole each have a first end attached directly to the inner periphery of the solid metal substrate and a second end that extends into the shaft hole.

In another aspect, the disclosure is directed to a sealing assembly comprising a scaling device comprising an annular substrate comprising an inner periphery defining a shaft hole and a plurality of carbon nanotubes extending outwardly from and around the inner; and a rotatable shaft disposed in the shaft hole. In one practice, in a fixed seal mounting to allow for shaft run-out and vibrations, the sealing assembly comprises a gap (e.g. of at least 100 μm) between the rotatable shaft and the plurality of carbon nanotubes extending outwardly from the inner periphery into the shaft hole. In another practice, in a floating seal mounting configuration, the plurality of carbon nanotubes that extend outwardly from the inner periphery into the shaft hole are disposed across the gap and are in scaling contact against the rotatable shaft. In one instance, the sealing contact prevents fluid from flowing from a first location to a second location, wherein the first location and the second location are disposed on opposite sides of the gap. The rotatable shaft can be associated with turbomachinery and like equipment, such as a gas compressor.

In another aspect, the disclosure is directed to a method for producing a sealing device comprising (i) coating each of a plurality of annular metal mesh substrates that have substantially the same outer diameter (OD) and substantially the same inner diameter (ID) with carbon nanotubes; (ii) mounting the plurality of carbon nanotube-coated annular metal mesh substrates axially onto a first annular frame member to form a stack of carbon nanotube-coated annular metal mesh substrates wherein one end of the stack is in contact with the first annular frame member, the first annular frame member having an outer diameter that is substantially the same as the outer diameter of the annular metal mesh substrates and an inner diameter defining a shaft hole, which inner diameter of the first annular frame is greater than the inner diameter of the annular metal mesh substrates so that a portion of the carbon nanotube-coated annular metal mesh substrate extends into the shaft hole; (iii) mounting a second annular frame member onto the other end of the stack, the second annular frame member having an outer diameter and an inner diameter that are each substantially the same as the outer and the inner diameter of the first annular frame member; and (iv) securing the first annular frame member, the stack, and the second annular frame member together for form the sealing device.

In another aspect, the disclosure is directed to a method for producing a sealing device comprising (i) providing a solid annular metal substrate comprising an inner periphery defining a shaft hole; and (ii) coating the inner periphery with a plurality of carbon nanotubes that extend into the shaft hole. In one practice, step (ii) comprises coating the solid annular metal substrate and the inner periphery with the plurality of carbon nanotubes, and removing the carbon nanotubes from the solid annular metal substrate except for the inner periphery to form the sealing device.

### BRIEF DESCRIPTION OF THE DRAWINGS

FIG. 1 is a schematic generally showing different stages of an embodiment of the method of making a sealing device of the disclosure.

FIG. 2 are SEM images of growing carbon nanotubes on the wires of a metal mesh substrate using (ii) ethanol and (iii) ethylene and ethanol and filling in the openings of the mesh, with panels (iv) to (vi) being enlargements of panels (i) to (iii) respectively.

FIG. 3A is a perspective view of a carbon nanotube brush ring as an exemplar of the second embodiment of the sealing device of the disclosure. FIG. 3B is a SEM image of the vertically aligned carbon nanotubes in the embodiment of FIG. 3A.

FIG. 4A is a plan view of an embodiment of a sealing assembly of the disclosure wherein there is a gap between the rotatable shaft and the carbon nanotubes of the sealing device. FIG. 4B is a plan view of another embodiment of a sealing assembly of the disclosure wherein the carbon nanotubes of the sealing device extend across the gap and are in contact with the rotatable shaft.

FIG. 5 is graph depicting static testing results of a sealing device of the disclosure as against known brush seals. The graph indicates that the flow coefficient on the set of carbon nanotube coated metal mesh sealing devices of the disclosure is one order of magnitude lower than that of known brush seals.

FIG. 6 is a schematic representing two methods, Route 1 and Route 1, to make a sealing device of the disclosure.

FIG. 7 depicts an assembly tool useful in a method to make a sealing device of the disclosure, with panel (i) showing a perspective view of the assembly tool with one annular steel frame, panel (ii) showing the assembly tool with annular mesh substrates in place, and panel (iii) showing a top view of an assembled sealing device with screws.

FIG. 8 is a graph depicting static seal rig testing results of a sealing device of the disclosure as against commercially available labyrinth and known brush seals. The sealing device of the disclosure showed 30% less leakage flow than the Haynes alloy brush seal.

FIG. 9 is a graph depicting static seal rig testing results of a sealing device of the disclosure as against commercially available labyrinth and known brush seals. The sealing device of the disclosure had >75% less leakage flow than the superalloy brush seal and increasingly better sealing efficiency than the Kevlar brush seal along with the pressure ratio (PR), e.g., 40% improvement at PR of 5.

### DETAILED DESCRIPTION

The entire contents of U.S. Published Patent Application No. 2021/0222290 are incorporated herein by reference for any purpose.

As used herein terms such as “a,” “an,” and “the” are not intended to refer to only a single entity but include the general class of which a specific example may be used for illustration. Terms defined herein in the singular are intended to include those terms defined in the plural and vice versa.

Reference to any numerical range as used herein expressly includes each numerical value (including fractional numbers and whole numbers) encompassed by that range and includes the endpoints of that range. For illustrative purposes only, a reference to a range of “0.0001 to 5000” includes whole numbers such as 5000, 4999, 4998 . . . 3, 2, 1; and includes fractional numbers such as 0.00011, 0.00012 . . . 0.1, 0.2, 0.3 . . . 1.1, 1.2, 1.3 . . . . 100.5, 100.6 . . . 4900.5, 4990.6, 4990.7 etc.

As used herein, the term “about” includes the value listed and indicates that the value listed may be somewhat altered, as long as the alteration does not result in nonconformance of the article or method or system herein described. For example, the term “about” as used herein can refer to a variation of between +1% up to +10%, including any value therebetween.

As used herein, the term “substantially”, or “substantial”, is equally applicable when used in a negative connotation to refer to the complete or near complete lack of an action, characteristic, property, state, structure, item, or result. For example, a surface that is “substantially” flat would either [be] completely flat, or so nearly flat that the effect would be the same as if it were completely flat.

The ensuing detailed description is made with reference to the figures. This is for convenience only and is not limiting to the scope of the disclosure.

In one aspect the disclosure is directed sealing device comprising an annular substrate comprising an inner periphery defining a shaft hole; and a plurality of carbon nanotubes (CNTs) extending outwardly from and around the inner periphery into the shaft hole. This includes, without limitation, carbon nanotubes that extend outwardly in any direction from and around the inner periphery into to the shaft hole.

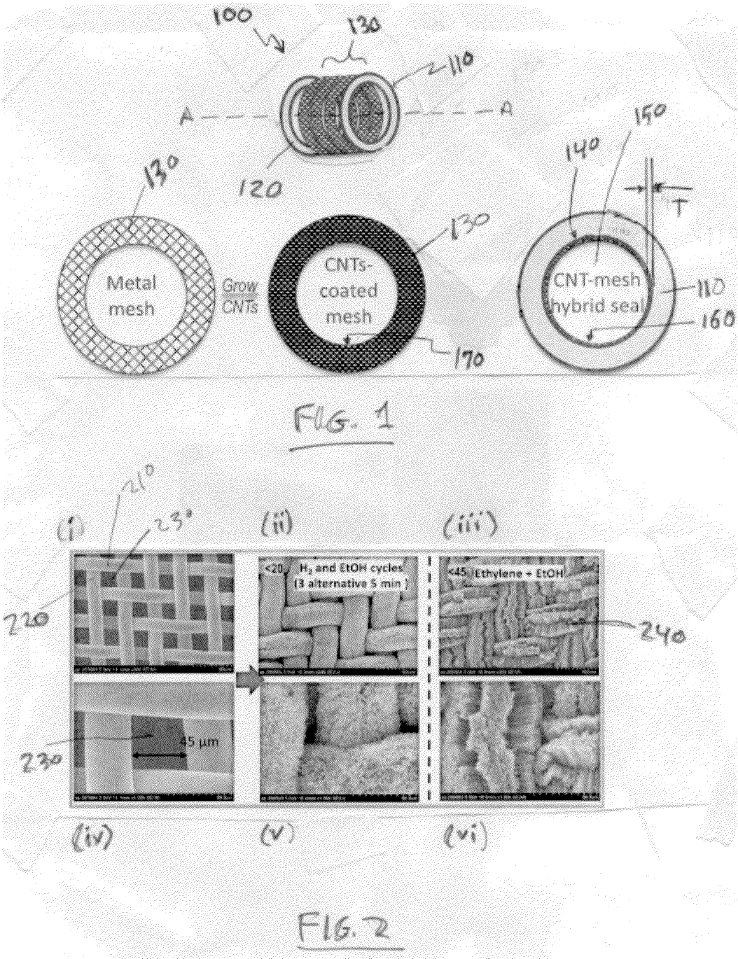

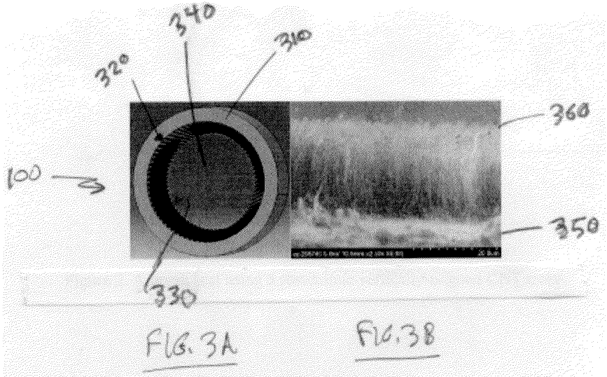

Referring to FIGS. 1 and 2, thereat is a first embodiment of the sealing device 100 of the disclosure (the first embodiment also referred to herein as the “CNT-metal mesh seal”) wherein the annular substrate is comprised of two portions, a first annular frame member 110 and a second annular frame member 120, each of which can be of the same or different material of construction, e.g. a metal such as stainless steel, aluminum, and the like, and can be substantially identical in size and shape. In one practice, first and second annular frames 110, 120 have flat top and bottom surfaces. Positionally, the second annular frame member 120 is axially disposed (axis A) to the first annular frame member 110. In the embodiment depicted, each of the first annular frame 110 and second annular frame 120 comprise an inner periphery 140 (shown only for the first annular frame) which defines shaft hole 150. One or a plurality of annular metal mesh substrates, without limitation up to 100 or more, e.g. 20-25 annular mesh substrates, e.g. 24 annular metal mesh substrates (a plurality of annular mesh substrates stacked together being shown in FIG. 1) 130 are axially (along axis A) interposed between the first annular frame 110 and the second annular frame 120. As shown, a portion 160 of the one or more annular metal substrates 130 extends outwardly from and around the inner periphery 140 into the shaft hole, the portion 160 comprising the carbon nanotubes. In one practice, portion 160 is coated with carbon nanotubes. The distance into which portion 160, and the carbon nanotubes thereon, extends into shaft hole 150 is shown by distance T. Without limitation, the carbon nanotubes can be multi-walled. In the practice shown in FIG. 1 and FIG. 2, the inner periphery 170 of the plurality of annular mesh substrates 130 is coated with carbon nanotubes 240 and forms part of the portion 160 that extends beyond the inner periphery 140 of the first and second annular frames 110, 120 and into shaft hole 150, the carbon nanotubes substantially covering each annular metal mesh substrate, including wires 210 and 220 and the like and any openings 230 therein due to the mesh structure. FIG. 2 shows carbon nanotubes grown on the wires of a metal mesh substrate to coat the wires 210, 220 of same and fill in the openings 230 of the mesh, with panels (iv) to (vi) being enlargements of panels (i) to (iii) respectively. In panel (ii) and (v) the carbon source was ethanol. In panel (iii) and (vi) the carbon source was a combination of ethanol and ethylene.

Annular mesh substrates 130 can be comprised of metal, including without limitation, a chromium-containing metal, such as stainless steel, e.g. 316 stainless steel and the like. In one practice, annular mesh substrates 130 can be flexible and can be comprised of fine metal wires or can include non-limiting configurations such as an expanded metal mesh, a perforated metal plate, a welded metal wire mesh, or a woven metal wire mesh. A coil configuration can also be used. In the embodiment shown, the annular mesh substrates 130 can either have the carbon nanotubes grown first, whereafter the annular mesh substrates are placed and secured to the first and second annular frames 110, 120 with portion 160 having the previously-grown carbon nanotubes extending into shaft hole 150; or alternatively, annular metal mesh substrates 130 can be placed and secured into first and second annular frames 110, 120 whereafter at portion 160 has the carbon nanotubes grown on it. First and second annular frames 110 ,120 and annular mesh substrates can be secured together to form the sealing device 100 by means known in the art, e.g., by screws, rivets and the like that extend though first annular frame 110, annular mesh substrates 130 to ad including second annular frame 120; alternatively, the screw holes can be sealed with or without screws present with glue, such as a super glue. The screw holes may also be countersunk to provide a flatter profile for the seal device. The advantage of the carbon nanotube-annular metal mesh seal using multiple fine-wire annular metal mesh layers stacked as a backbone and growing carbon nanotubes on them to fill the openings or gaps among the metal wires, as illustrated in FIGS. 1 and 2 eliminates the limitations of carbon nanotube length (which is length is at least coextensive with the annular metal mesh substrate itself and is thus unlimited) and improves the durability of the sealing device 100 (the very top and bottom annular mesh substrates, i.e. those in contact with annular frames 110, 120 protect the carbon nanotubes in the interior of the stack).

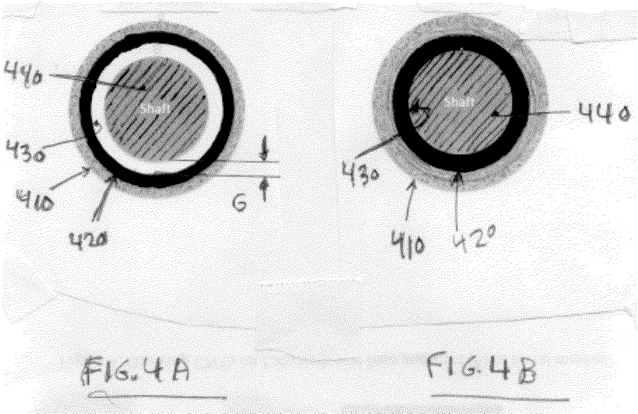

Referring to FIGS. 3A and 3B, thereat is a second embodiment of the sealing device 100 of the disclosure wherein annular substrate is a solid metal substrate 310, and the plurality of carbon nanotubes 330 that extend outwardly from and around the inner periphery 320 of solid metal substrate 310 into the shaft hole 340 each have a first end generally shown at 350 of FIG. 3B attached to the inner periphery 320 of the solid metal substrate and a second end generally shown as 360 that extends into the shaft hole 340. Solid metal substrate 310 can be comprised of metal, including without limitation, a chromium-containing metal, such as stainless steel, e.g. 316 stainless steel. In one practice, carbon nanotubes are grown in and around the inner periphery 320 of solid metal substrate 310 and over some or all of the remaining surface of solid metal substrate 310 whereafter the carbon nanotubes are removed from all surfaces by method known in the art except for inner periphery 320. Alternatively, carbon nanotubes can be grown only in and around inner periphery 320 by masking the remaining surfaces of solid metal substrate 310.

Referring to FIGS. 4A and 4B, thereat is another practice of the disclosure directed to a scaling assembly comprising a sealing device as described herein which comprises an annular substrate 410 comprising an inner periphery 420 defining a shaft hole (which includes gap G as shown in FIG. 4A) and a plurality of carbon nanotubes 430 that extending outwardly from and around the inner periphery 420; and a rotatable shaft 440 disposed in the shaft hole. In one practice, a fixed seal mounting to allow for shaft run-out and vibrations is shown in FIG. 4A where there is a gap G between the rotatable shaft 440 and the plurality of carbon nanotubes 430 extending outwardly from the inner periphery 420. The distance of gap G can vary as known in the art, e.g. G can be at least 100 um. In a second practice, a floating seal mounting configuration is shown in FIG. 4B wherein the plurality of carbon nanotubes 430 extend outwardly from the inner periphery 420 into the shaft hole so that they are disposed across the gap (gap G not being present) and are in scaling contact against the rotatable shaft 440. In one instance, the sealing contact prevents fluid, such as a liquid or a gas, from flowing from a first location to a second location, wherein the first location and the second location are disposed on opposite sides of the gap, e.g. along the axial direction of shaft 440. The rotatable shaft 440 can be associated with turbomachinery and like equipment, such as a gas compressor and in industries such as power generation, marine, automotive, and HVAC. The scaling assembly configuration of FIG. 4B permits the shaft freedom to move radially following shaft run out and vibrations, while the plurality of carbon nanotubes 430 are flexible and resilient and form an in situ low-friction protective carbon transfer film. In one practice, the brush seal configuration of the sealing device of the disclosure as shown in FIG. 3 using a standalone vertically-aligned plurality of carbon nanotubes requires the length of carbon nanotubes to match the gap clearance between the inner periphery and the shaft.

As compared to known sealing technology, the sealing device of the disclosure comprising carbon nanotubes includes 1) improved sealing efficiency due to ultra-low friction and high compliance. For example, the sealing device of the disclosure comprising carbon nanotubes is self-lubricating and has sustainable ultra-low friction. The self-lubricating ability and compliant seal structure of the sealing device of the disclosure comprising carbon nanotubes (in either the first or second embodiment) allows a nominal zero clearance to the shaft with little risk of wear damage on the seal or the shaft. As a result, this sealing device of the disclosure can significantly reduce the internal leakage flow as well as frictional loss and improve the turbomachinery efficiency compared to the state-of-the-art brush seals. 2) The sealing device of the disclosure comprising carbon nanotubes has improved sealing efficiency by providing a flexible base structure, e.g. when the annular mesh substrate comprises flexible material such as fine wire meshes. The sealing device of the disclosure comprising carbon nanotubes can employ CVD-based synthesis of the carbon nanotubes leading to less geometric restrictions in design, and which also permits the growing of carbon nanotubes on an annular mesh substrate comprising a flexible material such as fine wire meshes. This ability results in maintaining the seal-shaft clearance regardless of the shaft excursion and without creating cross-coupling forces disturbing shaft rotor-dynamics. 3) The sealing device of the disclosure comprising carbon nanotubes has improved seal durability and reliability, especially with the annular mesh substrate embodiment. The compliant multi-layer metal meshes serves as a backbone to not only eliminate the limitations of carbon nanotube length (which length is now coextensive with that of the mesh and is thus literally unlimited) but also protects the carbon nanotubes in between mesh layers with the very top and bottom layers. The durability and reliability of the carbon nanotube metal mesh seal outperforms the commercial carbon fiber brush seal. The self-lubricating characteristic of the carbon nanotubes avoids the shaft surface damage experienced by the commercial metal brush seal. 4) The sealing device of the disclosure comprising carbon nanotubes results in reduced manufacturing cost and the fabrication of the carbon nanotube based seals in both embodiments herein, is low and the process scalable. Current estimates indicate the cost will be between $10 to $50 for sealing device embodiments comprising carbon nanotubes embodiments described herein, which is about an order of magnitude lower than the metal or carbon fiber brush seals and about two orders of magnitude lower than the Kevlar brush seal. Table 1 summarizes some of the advantages of the sealing device of the disclosure comprising carbon nanotubes.

TABLE 1
Comparison between the carbon nanotube-based seals
of the disclosure (denoted CNT brush seal and CNT-
metal mesh seal) and known competitive technologies

| | Sealing | Durability/ | Shaft | Geometric | Cost |
|---|---|---|---|---|---|
| | efficiency | reliability | protection | flexibility | ($) |
| Labyrinth seal | Medium | Ok | Ok | Low | <30 |
| Metal brush seal | Medium- | Poor | Poor | Medium | 600 |
| | High | | | | |
| Carbon fiber | High | Poor | Good | Medium | 600 |
| brush seal | | | | | |
| Kevlar brush seal | High | Good | Good | Medium | 1800 |
| CNT brush seal | High | OK | Excellent | High | <50 |
| CNT-metal mesh | Very high | Excellent | Excellent | Medium | <50 |
| seal | | | | | |

### Example 1

Exemplars of the first (CNT-metal mesh in a frame) and second (a CNT brush ring) embodiments of the disclosure were prepared. For the first embodiment, a labyrinth seal base and a plurality of six (6) stacked annular mesh stainless steel (SS) mesh substrates in the form of disks were processed using a chemical vapor deposition (CVD) process as described below. All surfaces were coated with CNTs and the gaps between mesh wires were substantially filled in with CNTs. In one practice, the gaps or openings in the mesh are completely sealed over by the CNTs.

### Growth of CNTs

A “catalyst-free” CVD process as described in U.S. Published Patent Application No. 2021/0222290, the contents of which are incorporated herein by reference, was used to grow the CNTs for the sealing device. The growth of CNTs on Type 316 stainless steel (SS) is presented here. The SS substrate was used with or without pretreatments. The SS substrate was inserted into the CVD tube using a ceramic boat as known in the art. The CVD process consisted of five stages: (1) The SS substrate underwent thermal treatment from room temperature (RT) to a target temperature in the range of 600° C. to 800° C. under air flow of 20,000 sccm for over 30 minutes (temperature ramping varied from 20° C. to 30° C./min) under reduced pressure of 50 to 400 torr. The temperature was maintained at the target temperature for about 15 mins to further oxidize the SS surface; (2) The system was then vacuumed to remove the air and pressure was maintained at 0 to 5 torr for several minutes, e.g., 5 mins, before switching the CVD chamber to a reducing environment by supplying Ar/H₂ (e.g., 96% Ar and 4% H₂) at a flow rate of 100 to 500 ccm. The CVD chamber pressure was then brought to a higher level, e.g., 600 torr with Ar/H₂ gas flow, to improve reduction and was maintained at the target temperature for 30 to 60 minutes; (3) The Ar/H₂ flow was stopped and the CVD chamber vacuumed down to 0 to 5 torr to remove excess Ar/H₂; (4) Then, a carbon source (ethylene and ethanol) was introduced for 5 to 60 minutes depending on the samples at the target temperature; (5) Finally, heating was discontinued to allow the system to cool down to RT under Ar/H₂ flow of 50 to 500 ccm. During the step (1) and (3) the SS surfaces was oxidized and then reduced, essentially creating catalytic nano-scale features on the surface which features are believed to initiate the growth of the CNTs. Once the surface was ready in this regard, carbon sources were introduced under optimal gas flow rate and chamber pressure, which depend on the CNTs length, density, or surface coverage requirement. For example, FIG. 1 shows SS meshes with CNTs filling all gaps between the wires, and FIG. 3 shows a plurality of CNTs grown on a SS flat surface.

### Sealing Performance

Initial static seal testing was conducted on the 6-stack CNT-coated stainless steel mesh disks from and the results were compared with commercially available labyrinth seals and known brush seals. The set of stacked CNT-coated metal mesh disks (total thickness about 0.6 mm) were mounted on a static sea test rig as known in the art. A 66 mm diameter opening (shaft hole) was used (no shaft was present). Two labyrinth seals were used with 0.08 and 0.14 mm radial clearances, respectively, with respect to a 66 mm diameter shaft hole. The Labyrinth seal had a thickness of 10 mm. Three brush seals made from carbon fibers, Haynes alloy bristles, and Kevlar fibers were purchased from commercially.

In order to compare the performance between different seals with different physical flow area sizes, an orifice flow analogy was used as described in Jobson DA, “On the Flow of a Compressible Fluid Through Orifices,” Proceedings of the Institution of Mechanical Engineers, 1955;169(1):767-776. In the calculation, gravity and heat transfer were ignored and the effect of friction was assumed to be small. Isentropic changes of state on the gas was used over the range of testing conditions. The mass flow rate relate to theoretical flow is shown in Eq. (1). The performance of the different seals were evaluated by the flow coefficient C which represents the ratio between the vena contracta and the physical projected area.

\dot{m}=CK_{N}A\sqrt{P₀ρ₀} (1)

where:
K_{N}: Mass-flow coefficient,

$${K}_{N} = \sqrt{\frac{2 n}{n - 1} {r}^{2 / n} ( 1 - {r}^{\frac{n - 1}{n}} )}$$

\dot{m}: mass flow
C: flow coefficient
A: Projected area of orifice
P₀: Upstream flow pressure
ρ₀: Upstream flow density
n: Index of isentropic expansion (=γ for perfect gas)
r: pressure ratio

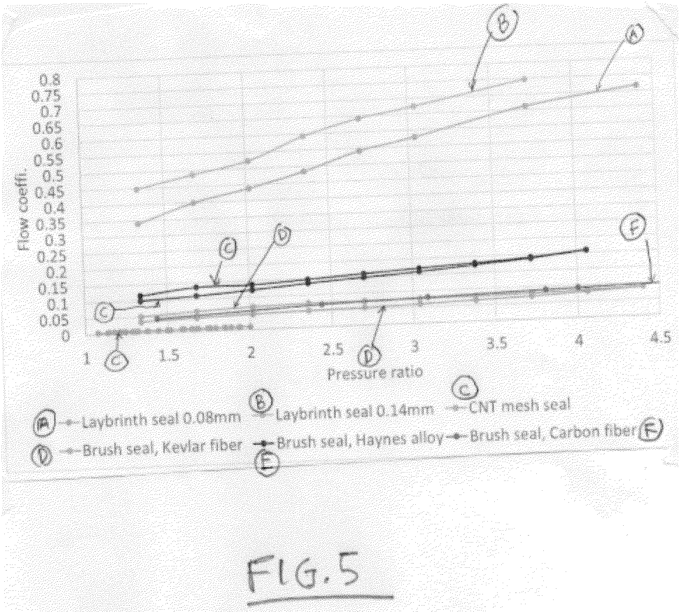

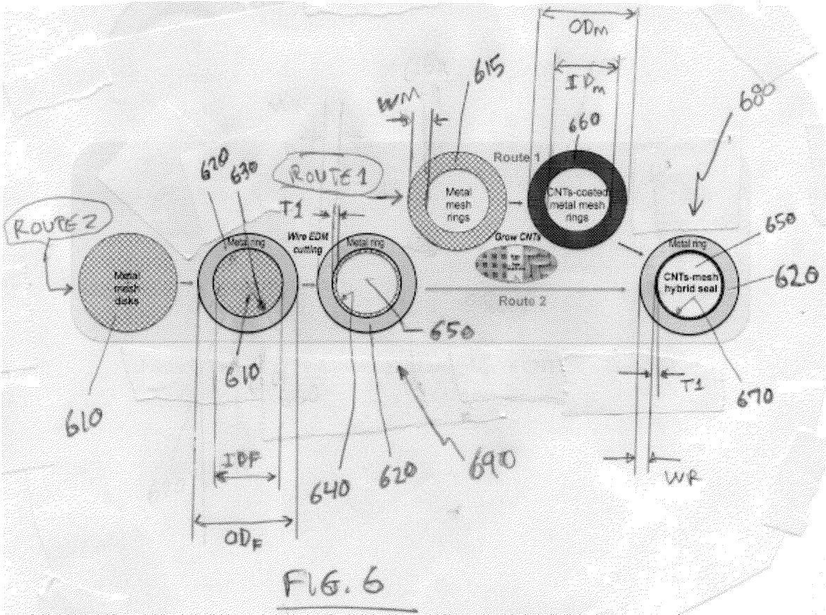

FIG. 5 graphically depicts the results of the comparison of the calculated flow coefficients based on measured mass flow rate of the different seals at different pressure ratios (PRs). A PR of 2 was limited on the CNT-coated metal mesh for safety reasons. No removal or damage of CNTs was observed visually after the test. The flow coefficient through the set 6-stacked CNT-coated metal mesh disks of the disclosure, denoted as “c” is one order of magnitude lower than those of the state-of-the-art brush seals denoted as “d,” “e,” and “f.”, which is indicative of superior sealing performance for the CNTs-coated mesh seal.

### CNT-metal Mesh Seal Fabrication

Two methods, Route 1 and Route 2, for fabricating and assembling a CNT-metal mesh seal are schematically shown in FIG. 6.

In Route 1, a metal mesh substrate 615 is provided. Metal mesh substrate 615 is shown as being annular in shape having a width WM, which is greater than the width WR of the annular frame member 620. Metal mesh substrate 615 has an outer circumference substantially the same as first annular frame member 620. Metal mesh substrate 615 is coated with carbon nanotubes 660 by e.g. the CVD process described herein and the result coated metal mesh substrate 660, or multiple such coated metal mesh substrates 660, are interposed between first annular frame 620 and its complementary second annular frame (not shown) on the backside, the resulting device being secured together by screws and the like as known in the art. Because metal mesh substrate has the same outer diameter as first annular frame 620 but is wider that first annular frame 620, when assembled axially, the carbon nanotubes 670 in the final sealing device 680 will extend into shaft hole 650 by distance T1. T1 being the approximate difference between WM and WR.

In Route 2, a metal mesh substrate 610 is provided. Metal mesh substrate 610 is shown as being circular, but it will be understood that any geometry of mesh can be used to start, and cut to a circular shape shown the outer circumference of metal mesh substrate 610 being substantially the same as the outer circumference of first annular frame 620. Metal mesh substrate 610, or a plurality of metal mesh substrates 610 are stacked and then interposed between first annular frame 620 and a second annular frame (not shown) on the backside and the entire assembly secured by screws and the like. Afterward, a portion of the metal mesh substrate extending across shaft hole 650 is removed by methods known in the art, e.g., electrical wire discharge cutting. Metal mesh substrate, which at this point is not coated with carbon nanotubes is cut so as to leave a portion of the metal mesh substrate 610 extending into shaft hole by distance T1 from inner periphery 630. The resulting assembly is then coated with carbon nanotubes 660 by e.g. the CVD process described herein, including metal mesh portion 640 to result in a carbon nanocoated mesh portion 670 which extends into shaft hole 650. In one practice, the entire pre-coated assembly 690 can be coated with carbon nanotubes, with those nanotubes constituting portion 670 being removed by means known in the art, e.g. scraping; or the entire pre-coated assembly 690 can be masked by means know in the art to selectively coat only portion 640 to result in carbon nanotube coated mesh portion 670. As shown, in one practice, first annular frame 620 has an outer diameter ODf and an inner diameter IDf, the inner diameter defines the inner periphery 630 which is substantially circular. The second annular frame (not shown) has an substantially the outer diameter ODf and inner diameter IDf and inner periphery which is substantially circular as the first annular metal frame 620. Metal mesh substrate 615 has an outer diameter ODm and an inner diameter IDm, which defines a substantially circular inner perimeter for the metal mesh substrates. In one practice, the outer diameters of the first annular frame, the second annular frame and the metal mesh substrate or substrates is substantially the same, and the inner diameter of the first annular frame and the second annular frame, which are substantially the same, is greater than the inner diameter of the metal mesh substrate or substrates so that a portion of the metal mesh substrates, e.g. 640, extends into the shaft hole, e.g. 650.

### Example 2

The method of Route 2 was used to make a sealing device of the disclosure. A stack of twelve (12) metal mesh substrates (316 stainless steel) were used. Machining debris from after the wire EDM cutting adhered to the stainless steel (SS) meshes which suppressed carbon nanotube (CNT) growth. The following initial cleaning and acid treatment was used to effectively clean the mesh by oxidizing the metal debris and dissolving the oxidation products in aqueous solutions. Two-steps are involved: (1) initial cleaning: sonicate with water and/or organic solvent to remove wear derbies and organic residues as much as possible (2) acid treatment to remove rest of the adhere wear debris.

Initial cleaning: Metal meshes were placed inside a 1000 mL beaker. Deionized water (DI) water (300 mL) was added and sonicated for 30 minutes at least three times to remove wear derbies. Same procedure can be repeated by mixing DI water with detergents. To remove organic residues, the sonication process proceeded with alcohol, Isopropanol, and toluene as solvents.

Acid treatment: Metal mesh rings (after the initial cleaning above) were placed inside the 1000 ml beaker. 2M HNO₃ (100 mL) was introduced and the solution stirred with a magnetic stir bar for at least 20 minutes until the brown color of the SS meshes disappeared. Then, metal meshes were washed with DI water several times to remove acid residue and vacuum-dried to remove water and moisture from the rings.

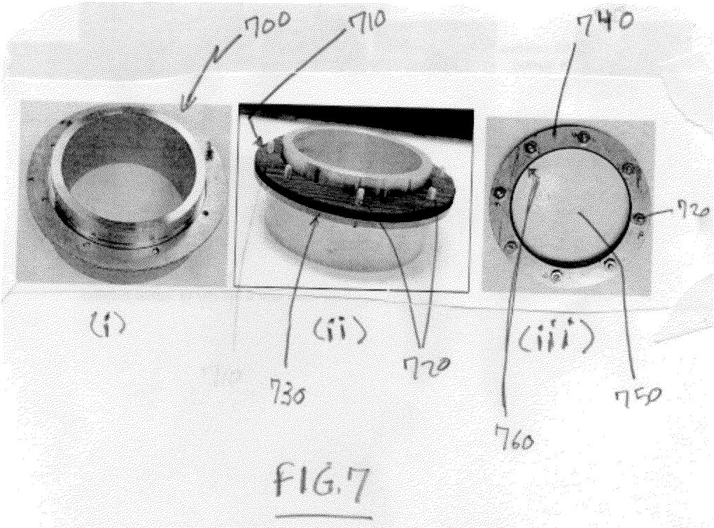

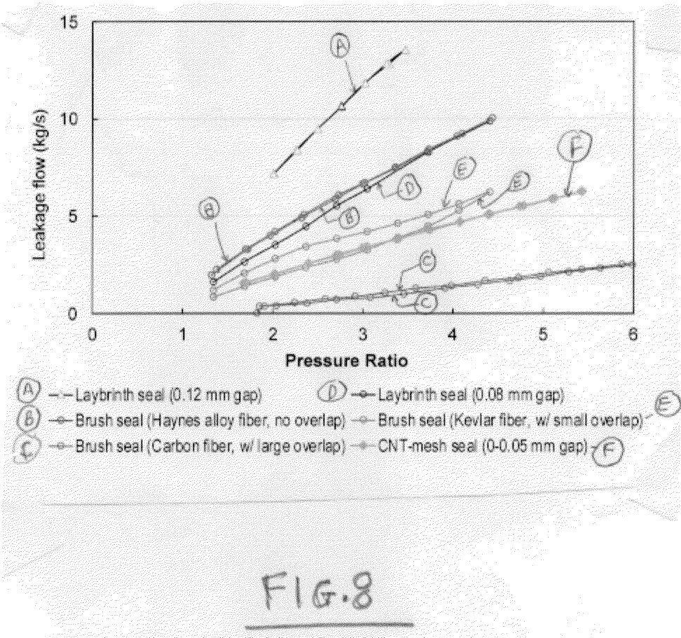

Assembly tool 700 as shown in panel (i) of FIG. 7 was used to assemble the metal meshes into seal configuration while maintaining seal concentricity. Other methods of achieving same are contemplated, the assembly tool being a non-limiting embodiment. In panel (ii), first annular metal frame 730 was placed on the assembly tool 700 with eight flat head screws 720. Then 24 annular CNT-coated metal mesh substrates of the disclosure 710 were carefully place on the annular metal frame 730, one by one to form a stack, guided by the eight screws 720 while maintaining concentricity provided by the assembly tool. Assembly tool 700 had an outer diameter of 66 mm. Then, a second annular metal frame 740 was placed on the other end of the stack, guided by eight screws. Then the eight screws were secured by nuts to provide the sealing device of the disclosure having shaft hole 750 into which a portion of the CNT-coated metal mesh substrates 760 extend, panel (iii). The eight screw holes can be machined with treads to secure screws and can be countersunk. In one practice, the first and second annular metal frames and each of the annular metal mesh substrates can have complementary through holes provided in their outer perimeters, which holes can accept screws, rivets and the like.

In one embodiment, the CNT-coated metal mesh sealing device of the disclosure had an outer diameter (OD) of 3.5 inches (which is the same as commercially available brush seals), a nominal inner diameter (ID) of 66 mm, a stack of 24 layers of CNT-coated stainless meshes, and a flat (planar) surface to better fit with the seal test rig and compressor.

### Static Seal Rig Testing of a Trial CNT-Metal Mesh Seal: Test 1

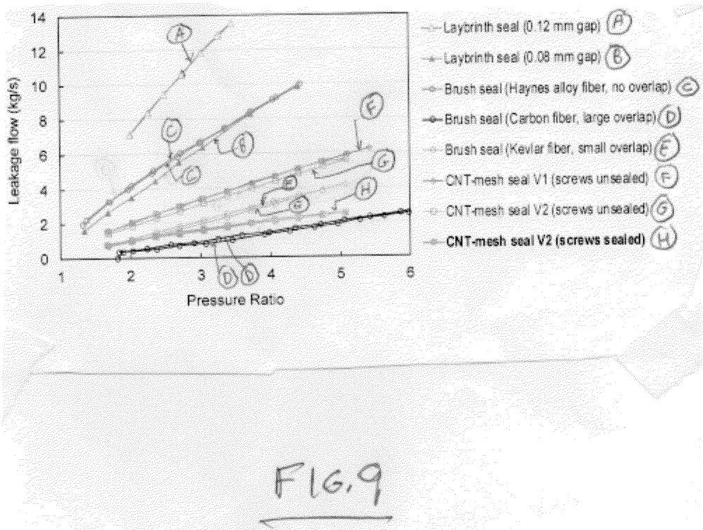

The static seal rig test was conducted on a CNT-mesh seal prepared using Route 1 in Example 2. The results were compared with results for commercially available labyrinth seal and known brush seals. A 66 mm diameter shaft was used for all the tests. The CNTs metal mesh seal had up to 0.05 mm radial clearance and 0.85 mm thickness (12 layers of 325×523 CNT-metal meshes each 0.85 mm thick with the screw holes in the sealing device secured by screws). Baselines include a labyrinth seals (denoted as “A” and “D”) with 0.14 mm radial clearance and a thickness of 10 mm and three commercial brush seals using Haynes alloy bristles (denoted as (“B”) (nominally no clearance or overlap, 1 mm thick), carbon fibers (denoted as “C”) (large overlap, several mm thick), and Kevlar fibers (denoted as “E”) (small overlap, several mm thick), respectively. The testing results are depicted in FIG. 8. Key observations are: 1) The CNT-metal mesh seal of the disclosure (“F”) showed 30% less leakage flow than the state-of-the-art Haynes alloy brush seal (“B”); 2) The CNT-metal mesh seal of the disclosure (“F”) showed similar sealing efficiency to the Kevlar brush seal (“E”). The Kevlar brush seal had demonstrated 1.8% improved overall compressor efficiency in compressor dyno test. 3) the carbon fiber brush seal (“C”) appeared to have the best sealing in the static rig because of its much larger radial overlap, which on the other hand, caused severe bristle damage in compressor dyno test.

### Static Seal Rig Testing of a Trial CNT-Metal Mesh Seal: Test 2

The static seal rig test was conducted on a CNT-mesh seal prepared using Route 1 in Example 2 and the results were compared the results with a commercially available labyrinth seals (denoted as “A” and “B”) and known. A 66 mm diameter shaft was used for all the tests. The CNT-mesh seal of test 2 (had 24 layers of CNT-coated stainless meshes (1.85 mm thick) and the screw holes sealed by commercially available superglue (denoted as “H”) or were not sealed by superglue (denoted as “G”), whereas the CNT-mesh seal used in test 1 (denoted in FIG. 9 as “F”) had 12 layers of CNT-coated stainless meshes (0.85 mm thick) and screw holes were not sealed with superglue. The testing results are depicted in FIG. 9. Key observations are: 1) The CNT-metal mesh seal of test 2 had >75% less leakage flow than the Haynes superalloy brush seal (denoted as “C”). 2) The CNT-metal mesh seal of test 2 showed increasingly better scaling efficiency than the Kevlar brush seal (denoted as “E”) along with the pressure ratio (PR), e.g., 40% improvement at the PR of 5. 3) The CNT-metal mesh seal of test 2 where the assembly screw holes sealed by superglue (“H”) showed significantly higher sealing efficiency than the CNT-metal mesh seal of test 1 (“F”), but both performed similarly otherwise. 3) The carbon fiber brush seal (denoted as D″) provided slightly better sealing than the CNT-metal mesh seal because of its much larger radial overlap, but it experienced severe bristle damage in compressor dyno test.

In another aspect, the disclosure is directed to a method for producing a sealing device comprising (i) coating each of a plurality of annular metal mesh substrates that have substantially the same outer diameter (OD) and substantially the same inner diameter (ID) with carbon nanotubes; (ii) mounting the plurality of carbon nanotube-coated annular metal mesh substrates axially onto a first annular frame member to form a stack of carbon nanotube-coated annular metal mesh substrates wherein one end of the stack is in contact with the first annular frame member, the first annular frame member having an outer diameter that is substantially the same as the outer diameter of the annular metal mesh substrates and an inner diameter defining a shaft hole, which inner diameter of the first annular frame is greater than the inner diameter of the annular metal mesh substrates so that a portion of the carbon nanotube-coated annular metal mesh substrate extends into the shaft hole; (iii) mounting a second annular frame member onto the other end of the stack, the second annular frame member having an outer diameter and an inner diameter that are each substantially the same as the outer and the inner diameter of the first annular frame member; and (iv) securing the first annular frame member, the stack, and the second annular frame member together for form a sealing device. In another practice the method above can be used using one annular metal mesh substrate. In one practice, the coating of carbon nanotubes onto the annular metal mesh substrates is by a chemical vapor deposition (CVD) process. In another practice, the annular metal mesh substrates comprise wires and are configured to have openings, and the carbon nanotubes coating covers the wires and the openings, including completely covering the wires and filling in the openings. The annular mesh substrates can be comprised of a chromium-containing metal, such as stainless steel and the like. In one practice, the annular mesh substrates, the first annular frame member and the second annular frame member each comprise complementary through holes into which screws or rivets and the like can be placed; the through holes can be countersunk. In one instance, the annular mesh substrates, the first annular frame member and the second annular frame member are secured together by placing screws, a sealant (such as a glue, e.g. a superglue), or both into the through holes.

In one practice, the CVD process used to provide the coated annular metal mesh substrates comprises (a) subjecting each of the plurality of annular metal mesh substrates to a surface oxidation process in which each of the plurality of annular metal mesh substrates is subjected to a first temperature of about 600° C. to about 1000° C. in an oxygen-containing atmosphere at a flow rate of greater than 1000 square cubic centimeters per minute (sccm) and under a first reduced pressure of at least 0.01 atm and less than 1 atm to result in oxidation of the surface of the inner periphery, wherein said first temperature is at least 100° C. below the melting point of the metal; (b) subjecting each of the plurality of annular metal mesh substrates to a surface reduction process in which each of the plurality of annular metal mesh substrates is subjected to a second temperature of between about 600° C. to about 1000° C. in a reducing atmosphere and under a second reduced pressure of at least 0.01 atm and less than 1 atm to result in reduction of the surface of each of the plurality of annular metal mesh substrates, wherein said reducing atmosphere contains hydrogen gas; (c) subjecting each of the plurality of annular metal mesh substrates to a third reduced pressure of no more than 0.1 atm; and (d) contacting each of the plurality of annular metal mesh substrates, while at the third reduced pressure and under an inert or reducing atmosphere, with an organic substance at a third temperature of between about 700° C. to about 900° C. for at least 1 minute, to result each of the plurality of annular metal mesh substrates being coated with carbon nanotubes. In one instance, the air flow rate is about 20,000 sccm. The organic substance in step (d) can have a molecular weight of up to 500 g/mol. In one practice, the organic substance the organic substance an alcohol or hydrocarbon. Non-limiting examples include organic substance is ethanol, ethylene and the like; combinations of organic substances may also be used. The method in step (b) can further comprise subjecting each of the plurality of annular metal mesh substrates to a surface oxidation process in which the annular metal substrate is elevated in temperature from room temperature to said first temperature of between about 600° C. to about 1000° C. at a temperature ramp rate of no more than 50° C./min in an oxygen-containing atmosphere and under a first reduced pressure of at least 0.1 atm and less than 1 atm to result in oxidation of a surface of each of the plurality of annular metal mesh substrates, wherein said first temperature is at least 100° C. below the melting point of the metal. The temperature ramp rate is no more than 40° C./min.

In another aspect, the disclosure is directed to a method for producing a sealing device, such as a carbon nanotube brush sealing device, comprising (i) providing a solid annular metal substrate comprising an inner periphery defining a shaft hole; and (ii) coating the inner periphery with a plurality of carbon nanotubes that extend into the shaft hole. In one practice, step (ii) comprises coating the solid annular metal substrate and the inner periphery with the plurality of carbon nanotubes, and removing the carbon nanotubes from the solid annular metal substrate except for the inner periphery to result in the sealing device.

What is claimed is:

1. A sealing device comprising:
an annular substrate comprising an inner periphery defining a shaft hole; and
a plurality of carbon nanotubes extending outwardly from and around the inner periphery into the shaft hole.

2. The sealing device of claim 1 wherein the annular substrate comprises a first annular frame member and a second annular frame member, the second annular frame member axially disposed to the first annular frame member; and comprises one or a plurality of annular metal mesh substrates axially interposed between the first annular frame and a second annular frame, wherein a portion of the one or more annular metal substrates extends outwardly from and around the inner periphery into the shaft hole, the portion comprising the carbon nanotubes.

3. The sealing device of claim 2 wherein the plurality of annular metal mesh substrates are are axially stacked together and interposed between the first annular frame and the second annular frame.

4. The sealing device of claim 3 wherein the plurality comprises up to 100 annular metal mesh substrates.

5. The sealing device of claim 2 wherein the one or the plurality of annular mesh substrates are flexible.

6. The sealing device of claim 2 wherein each of the annular metal substrates in the plurality of annular metal mesh substrates are substantially identical.

7. The sealing device of claim 2 wherein the annular metal mesh substrate comprises an expanded metal mesh, a perforated metal plate, a welded metal wire mesh, or a woven metal wire mesh.

8. The sealing device of claim 2 wherein the portion of the one or more annular metal substrates that extends outwardly from and around the inner periphery into the shaft hole comprises one or more openings and the carbon nanotubes substantially cover each annular metal mesh substrate and the one or more openings.

9. The sealing device of claim 3 wherein the first annular frame and the second annular frame are substantially identical, and the first annular frame and the second annular frame and the one or more annular metal substrates are attached.

10. The sealing device of claim 2 wherein the first annular frame and the second annular frame are substantially identical and each individually comprise a metal.

11. The sealing device of claim 1 wherein the annular substrate comprises a solid metal substrate, and the plurality of carbon nanotubes that extend outwardly from and around the inner periphery into the shaft hole each have a first end attached to the inner periphery of the solid metal substrate and a second end that extends into the shaft hole.

12. The sealing device of claim 1 wherein the sealing device is configured to be mounted on a rotatable shaft.

13. A sealing assembly comprising:
a sealing device comprising an annular substrate comprising an inner periphery defining a shaft hole and a plurality of carbon nanotubes extending outwardly from and around the inner; and
a rotatable shaft disposed in the shaft hole.

14. The sealing assembly of claim 13 comprising a gap between the rotatable shaft and the plurality of carbon nanotubes extending outwardly from the inner periphery into the shaft hole.

15. The sealing assembly of claim 14 wherein the gap is no less than 100 μm.

16. The sealing assembly of claim 14 wherein the plurality of carbon nanotubes extending outwardly from the inner periphery into the shaft hole are disposed across the gap and are in sealing contact against the rotatable shaft.

17. The sealing assembly of claim 16 wherein the sealing contact prevents fluid from flowing from a first location to a second location, wherein the first location and the second location are disposed on opposite sides of the gap.

18. The sealing assembly of claim 17 wherein the fluid is a gas.

19. The sealing assembly of claim 13 wherein the annular substrate comprises a first annular frame member and a second annular frame member, the second annular frame member axially disposed to the first annular frame member; and a plurality of annular metal mesh substrates axially stacked together and interposed between the first annular frame and the second annular frame, wherein a portion of the plurality of annular metal substrates extends outwardly from and around the inner periphery into the shaft hole, the portion comprising the carbon nanotubes.

20. A method for producing a sealing device comprising:
(i) coating each of a plurality of annular metal mesh substrates that have substantially the same outer diameter (OD) and substantially the same inner diameter (ID) with carbon nanotubes;
(ii) mounting the plurality of carbon nanotube-coated annular metal mesh substrates axially onto a first annular frame member to form a stack of carbon nanotube-coated annular metal mesh substrates wherein one end of the stack is in contact with the first annular frame member, the first annular frame member having an outer diameter that is substantially the same as the outer diameter of the annular metal mesh substrates and an inner diameter defining a shaft hole, which inner diameter of the first annular frame is greater than the inner diameter of the annular metal mesh substrates so that a portion of the carbon nanotube-coated annular metal mesh substrate extends into the shaft hole;
(iii) mounting a second annular frame member onto the other end of the stack, the second annular frame member having an outer diameter and an inner diameter that are each substantially the same as the outer and the inner diameter of the first annular frame member; and
(iv) securing the first annular frame member, the stack, and the second annular frame member together for form a sealing device.

21. The method of claim 20 wherein in step (i) the coating of carbon nanotubes onto the annular metal mesh substrates is by a chemical vapor deposition (CVD) process.

22. The method of claim 21 wherein the annular metal mesh substrates comprise wires and are configured to have openings, and the carbon nanotubes coating covers the wires and the openings.

23. The method of claim 20 wherein the annular mesh substrates are comprised of a chromium-containing metal.

24. The method of claim 20 wherein the annular mesh substrates, the first annular frame member and the second annular frame member each comprise complementary through holes.

25. The method of claim 24 wherein in step (iv) the annular mesh substrates, the first annular frame member and the second annular frame member are secured together by placing screws, a sealant, or both into the through holes.

26. The method of claim 25 further comprising in step (iv) wherein the sealant if a glue.

27. The method of claim 21 wherein the CVD process comprises:
(a) subjecting each of the plurality of annular metal mesh substrates to a surface oxidation process in which each of the plurality of annular metal mesh substrates is subjected to a first temperature of about 600° C. to about 1000° C. in an oxygen-containing atmosphere at a flow rate of greater than 1000 square cubic centimeters per minute (sccm) and under a first reduced pressure of at least 0.01 atm and less than 1 atm to result in oxidation of the surface of the inner periphery, wherein said first temperature is at least 100° C. below the melting point of the metal;
(b) subjecting each of the plurality of annular metal mesh substrates to a surface reduction process in which each of the plurality of annular metal mesh substrates is subjected to a second temperature of between about 600° C. to about 1000° C. in a reducing atmosphere and under a second reduced pressure of at least 0.01 atm and less than 1 atm to result in reduction of the surface of each of the plurality of annular metal mesh substrates, wherein said reducing atmosphere contains hydrogen gas;
(c) subjecting each of the plurality of annular metal mesh substrates to a third reduced pressure of no more than 0.1 atm; and
(d) contacting each of the plurality of annular metal mesh substrates, while at the third reduced pressure and under an inert or reducing atmosphere, with an organic substance at a third temperature of between about 700° C. to about 900° C. for at least 1 minute, to result each of the plurality of annular metal mesh substrates being coated with carbon nanotubes.

28. The method of claim 27 wherein the flow rate is about 20,000 sccm.

29. The method of claim 17 wherein the organic substance in step (d) has a molecular weight of up to 500 g/mol.

30. The method of claim 27 wherein the organic substance in step (d) is an alcohol or hydrocarbon.

31. The method of claim 27 wherein step (b) comprises subjecting each of the plurality of annular metal mesh substrates to a surface oxidation process in which the annular metal substrate is elevated in temperature from room temperature to said first temperature of between about 600° C. to about 1000° C. at a temperature ramp rate of no more than 50° C./min in an oxygen-containing atmosphere and under a first reduced pressure of at least 0.1 atm and less than 1 atm to result in oxidation of a surface of each of the plurality of annular metal mesh substrates, wherein said first temperature is at least 100° C. below the melting point of the metal.

32. The method of claim 27, wherein said temperature ramp rate is no more than 40° C./min.

33. A method for producing a sealing device comprising:
(i) providing a solid annular metal substrate comprising an inner periphery defining a shaft hole; and
(ii) coating the inner periphery with a plurality of carbon nanotubes that extend into the shaft hole.

34. The method of claim 33 wherein step (ii) comprises coating the solid annular metal substrate and the inner periphery with the plurality of carbon nanotubes, and removing the carbon nanotubes from the solid annular metal substrate except for the inner periphery,
